(19) United States
(12) Patent Application Publication
(10) Pub. No.: US 2009/0091730 A1
(43) Pub. Date: Apr. 9, 2009

(54) SPATIAL LIGHT MODULATION UNIT, ILLUMINATION APPARATUS, EXPOSURE APPARATUS, AND DEVICE MANUFACTURING METHOD

(75) Inventor: Hirohisa TANAKA, Kumagaya-shi (JP)

Correspondence Address: MILES & STOCKBRIDGE PC, 1751 PINNACLE DRIVE, SUITE 500, MCLEAN, VA, 22102-3833, US

(73) Assignee: NIKON CORPORATION

(21) Appl. No.: 12/208,155

(22) Filed: Sep. 10, 2008

Related U.S. Application Data
(60) Provisional application No. 60/960,546, filed on Oct. 3, 2007.

(51) Int. Cl. G03F 7/20; G02B 26/00

(52) U.S. Cl. 355/67; 359/298; 359/290

(57) ABSTRACT

A spatial light modulation unit can be arranged in an optical system and can be arranged along an optical axis of the optical system. The spatial light modulation unit includes a first folding surface which folds light incident in parallel with the optical axis of the optical system; a reflective spatial light modulator which folds the light folded on the first folding surface; and a second folding surface which folds the light folded on the spatial light modulator, to emit the light into the optical system. The spatial light modulator applies spatial modulation to the light, according to a position where the light folded on the first folding surface is incident to the spatial light modulator.

### CROSS-REFERENCE TO RELATED APPLICATIONS

This application is based upon and claims the benefit of priorities from U.S. Provisional Application No. 60/960,546, filed on Oct. 3, 2007, the entire contents of which are incorporated herein by reference.

### BACKGROUND OF THE INVENTION

1. Field

An embodiment of the present invention relates to a spatial light modulation unit, an illumination apparatus, an exposure apparatus, and a device manufacturing method.

2. Description of the Related Art

A reflective spatial light modulator is known as a conventional spatial modulator to form a pupil luminance distribution for modified illumination (e.g., a dipolar, quadrupolar, or other distribution) in an exposure apparatus (e.g., cf. Japanese Patent Application Laid-open No. 2002-353105). In the Application Laid-open No. 2002-353105, the reflective spatial light modulator is so arranged that light is obliquely incident to the reflective spatial light modulator, in order to separate an incident light path to the spatial light modulator from an exiting light path (reflected light path) from the spatial light modulator, without significant change in a configuration of an illumination optical system in the exposure apparatus.

### SUMMARY

An embodiment of the present invention provides a spatial light modulation unit that can be arranged in an optical system so as to form a desired light path.

A spatial light modulation unit according to an embodiment of the present invention is a spatial light modulation unit that can be arranged in an optical system and that can be arranged along an optical axis of the optical system, the spatial light modulation unit comprising: a first folding surface to fold light incident in parallel with the optical axis of the optical system; a reflective spatial light modulator to reflect the light folded on the first folding surface; and a second folding surface to fold the light reflected on the spatial light modulator, and to send forth the light into the optical system; wherein the spatial light modulator applies spatial modulation to the light, according to a position where the light folded on the first folding surface is incident to the spatial light modulator.

The spatial light modulation unit comprises the spatial light modulator which applies the spatial modulation to the light, according to the position of incidence thereof. For this reason, it is able to form a desired pupil luminance distribution, e.g., a dipolar, quadrupolar, or other distribution. It also comprises the first and second folding surfaces in addition to the reflective spatial light modulator. For this reason, it can be arranged in the optical system so as to form a desired optical path.

An illumination apparatus according to an embodiment is an illumination apparatus which illuminates a first surface with light supplied from a light source, the illumination apparatus comprising the aforementioned spatial light modulation unit.

An illumination apparatus according to another embodiment is an illumination apparatus which illuminates an illumination target surface on the basis of light from a light source, the illumination apparatus comprising: a spatial light modulator including a plurality of optical elements arranged two-dimensionally and controlled individually; a diffractive optical element which can be arranged in the illumination apparatus; a first optical path in which the spatial light modulator can be arranged at a first position thereof; a second optical path in which the diffractive optical element can be arranged at a second position thereof; a third optical path being an optical path between the light source and the first optical path and optical path between the light source and the second optical path; and a fourth optical path being an optical path between the first optical path and the illumination target surface and optical path between the second optical path and the illumination target surface; wherein the first optical path and the second optical path are switchable from one to the other, and wherein an optical axis at an exit of the third optical path and an optical axis at an entrance of the fourth optical path are coaxial.

An illumination apparatus according to still another embodiment is an illumination apparatus which illuminates a first surface with light supplied from a light source, the illumination apparatus comprising a spatial light modulation unit comprising: a spatial light modulator which applies spatial modulation to the light according to a position of incidence thereof; and a diffractive optical element which forms a first pupil luminance distribution with light not passing via the spatial light modulator of the spatial light modulation unit;

the illumination apparatus being configured to form a second pupil luminance distribution overlapping at least in part with the first pupil luminance distribution, with light from the spatial light modulator of the spatial light modulation unit.

An exposure apparatus according to an embodiment is an exposure apparatus which projects an image of a first surface onto a second surface, the exposure apparatus comprising the aforementioned illumination apparatus to illuminate the first surface; and a projection optical system which forms the image of the first surface on the second surface, based on light from an illumination region formed on the first surface by the illumination apparatus.

A device manufacturing method according to an embodiment comprises: preparing a photosensitive substrate; arranging the photosensitive substrate on the second surface in the aforementioned exposure apparatus and projecting an image of a predetermined pattern located on the first surface, onto the photosensitive substrate to effect exposure thereof; developing the photosensitive substrate onto which the image of the pattern has been projected, to form a mask layer in a shape corresponding to the pattern on a surface of the photosensitive substrate; and processing the surface of the photosensitive substrate through the mask layer.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is a configuration diagram schematically showing an exposure apparatus according to the first embodiment.

FIG. 2 is a drawing for explaining a relation of arrangement of a spatial light modulation unit and a diffractive optical unit.

FIG. 3 is a drawing for explaining another relation of arrangement of the spatial light modulation unit and the diffractive optical unit.

FIG. 4 is a drawing for explaining a configuration in a IV-IV cross section of the spatial light modulation unit shown in FIG. 2.

FIG. 5 is a partial perspective view of a spatial light modulator which the spatial light modulation unit has.

FIG. 6 is a drawing showing a shape of an illumination field in the case of annular illumination.

FIG. 7 is a flowchart of a method of manufacturing semiconductor devices.

FIG. 8 is a flowchart of a method of manufacturing a liquid-crystal display device.

FIG. 9 is a configuration diagram schematically showing a maskless exposure apparatus which is a modification example of the exposure apparatus according to the first embodiment.

FIG. 10 is a configuration diagram schematically showing an exposure apparatus according to the second embodiment.

FIG. 11 is a drawing for explaining arrangement of the spatial light modulation unit.

FIG. 12 is a drawing showing a pupil luminance distribution formed by a light beam passing the diffractive optical unit but not passing the spatial light modulation unit.

FIG. 13 is a drawing showing a pupil luminance distribution formed by a light beam not passing the diffractive optical unit but passing the spatial light modulation unit.

FIG. 14 is a drawing showing a pupil luminance distribution resulting from superposition of the first and second pupil luminance distributions on a pupil plane.

FIG. 15 is a drawing for explaining arrangement of another spatial light modulation unit.

FIG. 16 is a drawing for explaining arrangement of the spatial light modulation unit.

### DESCRIPTION

Embodiments of the present invention will be described below in detail with reference to the accompanying drawings. It is noted that in the description the same elements or elements with the same functionality will be denoted by the same reference symbols, without redundant description.

### First Embodiment

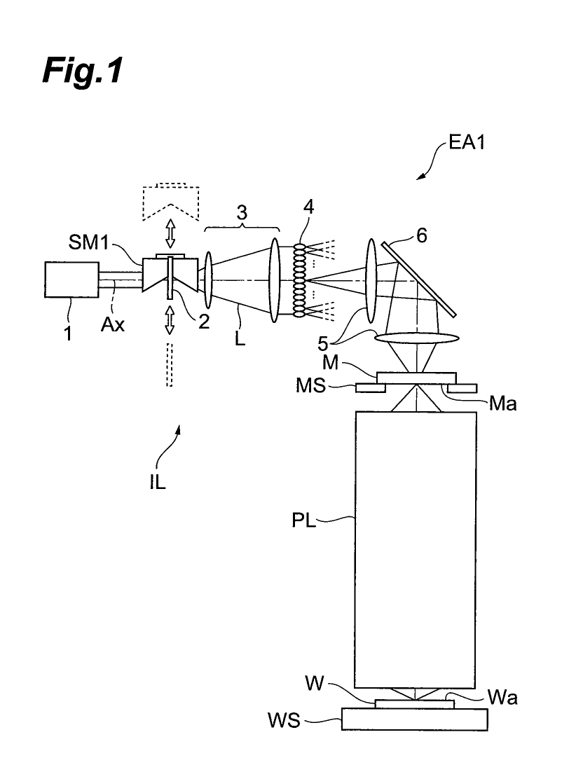

A configuration of an exposure apparatus EA1 according to the first embodiment will be described with reference to FIG. 1. FIG. 1 is a configuration diagram schematically showing the exposure apparatus of the first embodiment.

The exposure apparatus EA1 of the first embodiment has an illumination apparatus IL provided with a spatial light modulation unit SM1, a mask stage MS supporting a mask M, a projection optical system PL, and a wafer stage WS supporting a wafer W, along the optical axis Ax of the apparatus. The exposure apparatus EA1 illuminates the mask M by the illumination apparatus IL, based on light supplied from a light source 1, and projects an image of a first surface being a surface Ma on which a pattern of the mask M is formed, onto a second surface being a projection surface Wa on the wafer W, using the projection optical system PL. The illumination apparatus IL, which illuminates the first surface being the surface Ma with the pattern of the mask M thereon, with the light supplied from the light source 1, performs modified illumination, e.g., dipolar, quadrupolar, or other illumination by the spatial light modulation unit SM1.

The illumination apparatus IL has the spatial light modulation unit SM1, a diffractive optical unit 2, a zoom optical system 3, a fly's eye lens 4, a condenser optical system 5, and a folding mirror 6 along the optical axis Ax. Each of the spatial light modulation unit SM1 and the diffractive optical unit 2 can be inserted into or retracted from the optical path of the illumination apparatus IL. The spatial light modulation unit SM1 and the diffractive optical unit 2 each form a desired pupil luminance distribution in their far field.

The fly's eye lens 4 is so configured that a plurality of lens elements are arranged two-dimensionally and densely. The plurality of lens elements forming the fly's eye lens 4 are so arranged that the optical axis of each lens element becomes parallel to the optical axis Ax being the optical axis of the illumination apparatus IL including the fly's eye lens 4, and optical axis of the exposure apparatus. The fly's eye lens 4 divides the wavefront of incident light to form a secondary light source consisting of light source images as many as the lens elements on a rear focal plane thereof. Since in the present example the mask M located on an illumination target surface is illuminated by Köhler illumination, the plane on which this secondary light source is formed is a plane conjugate with an aperture stop of the projection optical system PL and can be called an illumination pupil plane of the illumination apparatus IL. Typically, the illumination target surface (the surface on which the mask M is arranged or the surface on which the wafer W is arranged) becomes an optical Fourier transform surface with respect to the illumination pupil plane. The pupil luminance distribution is a luminance distribution on the illumination pupil plane of the illumination apparatus IL or on a plane conjugate with the illumination pupil plane. However, when the number of wavefront divisions by the fly's eye lens 4 is large, an overall luminance distribution formed on the entrance surface of the fly's eye lens 4 shows a high correlation with the overall luminance distribution of the entire secondary light source (pupil luminance distribution), and, therefore, the luminance distributions on the entrance surface of the fly's eye lens 4 and on a plane conjugate with the entrance surface can also be called pupil luminance distributions.

The condenser optical system 5 condenses light exiting from the fly's eye lens 4 and illuminates the mask M on which the predetermined pattern is formed. The folding mirror 6 is arranged in the condenser optical system 5 and folds the optical path of the light beam passing through the condenser optical system. The mask M is mounted on the mask stage MS.

The projection optical system PL forms an image of the first surface on the projection surface (second surface) Wa of the wafer W mounted on the wafer stage WS, based on light from an illumination region formed on the pattern surface (first surface) Ma of the mask M by the illumination apparatus IL.

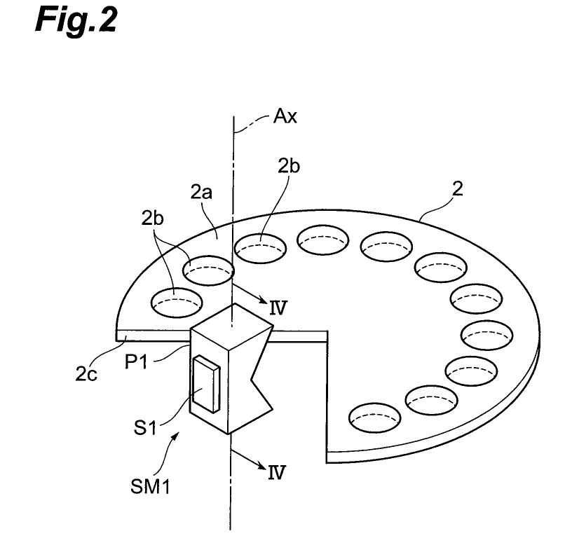

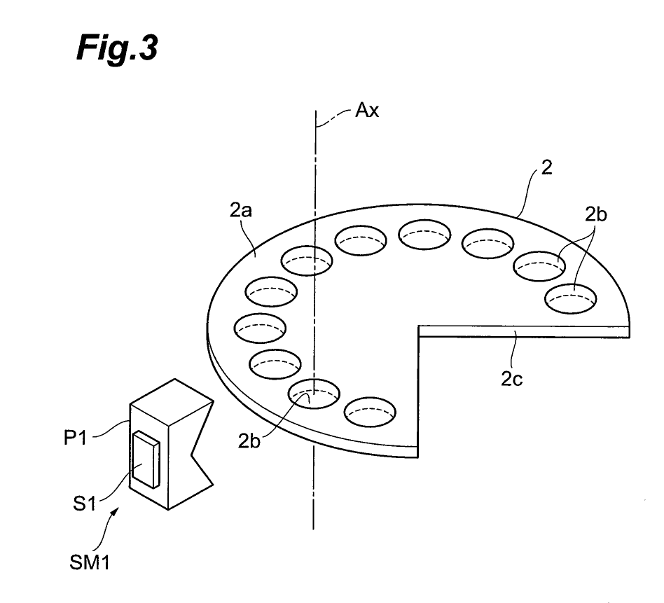

The following will describe a relation of arrangement of the spatial light modulation unit SM1 and the diffractive optical unit 2 with reference to FIGS. 2 and 3. FIG. 2 is a drawing for explaining the arrangement in the case where the spatial light modulation unit SM1 is inserted along the optical axis Ax of the exposure apparatus EA1. FIG. 3 is a drawing for explaining the arrangement in the case where the spatial light modulation unit SM1 is located off the optical axis Ax of the exposure apparatus EA1 and where one of a plurality of diffractive optical elements 2b in the diffractive optical unit 2 is inserted along the optical axis Ax of the exposure apparatus EA1.

As shown in FIGS. 2 and 3, the diffractive optical unit 2 has a turret member 2a in which a notch 2c is formed, and a plurality of diffractive optical elements 2b formed on the turret member 2a. The diffractive optical elements 2b are made by forming level differences with a pitch approximately equal to the wavelength of exposure light (illumination light), in the turret member 2a, and have an action to diffract an incident beam at desired angles.

As shown in FIG. 2, the spatial light modulation unit SM1 can be arranged on the optical axis Ax of the exposure apparatus EA1 when it is arranged to be inserted in a space created by the notch 2c of the diffractive optical unit 2, in a fixed state of the diffractive optical unit 2. As shown in FIG. 3, the spatial light modulation unit SM1 can also be located off the optical axis Ax of the exposure apparatus EA1 when it is moved away from inside the notch 2c of the diffractive optical unit 2 in the fixed state of the diffractive optical unit 2. Alternatively, the diffractive optical unit 2 may be moved in a fixed state of the spatial light modulation unit SM1. In this manner, the spatial light modulation unit SM1 can be arranged along the optical axis Ax of the exposure apparatus EA1 or along the optical axis Ax of the illumination apparatus IL.

Since the spatial light modulation unit SM1 is greater in size and mass than the diffractive optical unit 2, it is not mounted on the same turret member 2a but is arranged in the notch 2c of the diffractive optical unit 2. Since a cable for transmission of drive signals is connected to the spatial light modulation unit SM1, the unit SM1 does not have to be mounted on the turret while trailing the cable, in the configuration where it is arranged in the notch 2c.

When the spatial light modulation unit SM1 is moved away from the optical axis Ax, as shown in FIG. 3, the diffractive optical unit 2 is arranged in a state in which the axis of rotation thereof is parallel to the optical axis Ax and eccentric to the optical axis Ax. Then it is rotated so that one of the plurality of diffractive optical elements 2b in the turret member 2a is located on the optical axis Ax. In the turret member 2a, as shown in FIGS. 2 and 3, the diffractive optical elements 2b are arranged along the circumferential direction thereof. The diffractive optical elements 2b are elements each of which diffracts an incident beam to produce a plurality of beams eccentric to the optical axis Ax, and are set to have their respective different diffraction properties (e.g., angles of diffraction).

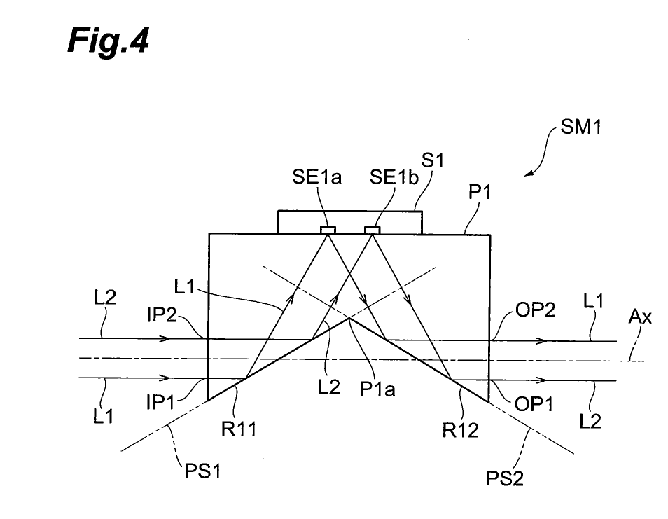

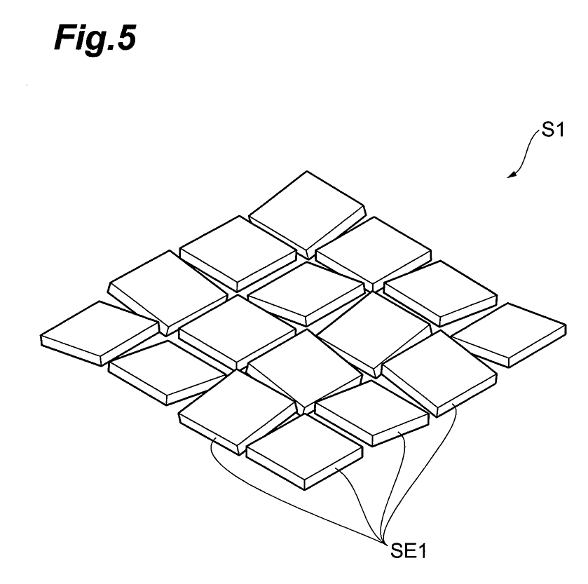

The configuration of the spatial light modulation unit SM1 will be described below with reference to FIGS. 4 and 5. FIG. 4 is a drawing for explaining the configuration in a IV-IV cross section of the spatial light modulation unit SM1 shown in FIG. 2. FIG. 5 is a partial perspective view of a spatial light modulator S1 in the spatial light modulation unit SM1. FIG. 4 is depicted without hatching for cross sections, for better viewing.

As shown in FIG. 4, the spatial light modulation unit SM1 has a prism P1, and a reflective spatial light modulator S1 attached integrally to the prism P1. The prism P1 is made of a glass material, e.g., fluorite. The prism P1 is of a shape in which one side face of a rectangular parallelepiped is depressed in a V-shaped wedge form. Namely, in the prism P1 the one side face of the rectangular parallelepiped is composed of two planes PS1, PS2 (first and second planes PS1, PS2) intersecting at an obtuse angle as an intersecting line (straight line) P1a between them subsides inside. The spatial light modulator S1 is attached onto a side face facing both of these two side faces in contact at the intersecting line P1a. The optical material forming the prism P1 is not limited to fluorite, but it may be silica glass or other optical glass.

Internal surfaces of these two side faces in contact at the intersecting line P1a function as first and second reflecting surfaces R11, R12. Therefore, the first reflecting surface R11 is located on the first plane PS1. The second reflecting surface R12 is located on the second plane PS2 intersecting with the first plane PS1. The angle between the first and second reflecting surfaces R11, R12 is an obtuse angle.

The angles herein may be determined, for example, as follows: the angle between the first and second reflecting surfaces R11, R12 is 120°; the angle between the side face of the prism P1 perpendicular to the optical axis Ax and the first reflecting surface R11 is 60°; the angle between the side face of the prism P1 perpendicular to the optical axis Ax and the second reflecting surface R12 is 60°.

The prism P1 is so arranged that the side face to which the spatial light modulator S1 is attached is parallel to the optical axis Ax, that the first reflecting surface R11 is located on the light source 1 side (upstream in the exposure apparatus EA1), and that the second reflecting surface R12 is located on the fly's eye lens 4 side (downstream in the exposure apparatus EA1). Therefore, the first reflecting surface R11 of the prism P1 is obliquely arranged with respect to the optical axis Ax of the exposure apparatus EA1, as shown in FIG. 4. The second reflecting surface R12 of the prism P1 is also obliquely arranged with an opposite inclination to the first reflecting surface R11 with respect to the optical axis Ax of the exposure apparatus EA1, as shown in FIG. 4.

The first reflecting surface R11 of the prism P1 reflects light incident in parallel with the optical axis Ax of the exposure apparatus EA1. The spatial light modulator S1 is arranged in the optical path between the first reflecting surface R11 and the second reflecting surface R12 and reflects the light reflected on the first reflecting surface R11. The second reflecting surface R12 of the prism P1 reflects the light reflected on the spatial light modulator S1 and emits the reflected light into the illumination apparatus IL of the exposure apparatus EA1, specifically, into the zoom optical system 3.

Therefore, the intersecting line P1a being a ridge line formed by the first and second planes PS1, PS2 is located on the spatial light modulator S1 side with respect to the first and second reflecting surfaces R11, R12.

The prism P1 in the present example is integrally formed of one optical block, but the prism P1 may also be constructed using a plurality of optical blocks.

The spatial light modulator S1 applies spatial modulation to the light, according to a position where the light reflected on the first reflecting surface R11 is incident to the spatial light modulator S1. The spatial light modulator S1, as described below, includes a large number of micro mirror elements SE1 arranged two-dimensionally. For this reason, for example, a ray L1 in the light beam incident to the spatial light modulator S1 impinges on a mirror element SE1a out of the plurality of mirror elements SE1 of the spatial light modulator S1, and a ray L2 impinges on a mirror element SE1b different from the mirror element SE1a out of the plurality of mirror elements SE1 of the spatial light modulator S1. The mirror elements SE1a, SE1b apply their respective spatial modulations set according to their positions, to the rays L1, L2, respectively. The spatial light modulator S1 modulates the light so that the light reflected on the second reflecting surface R12 to be emitted into the zoom optical system 3 becomes parallel to the incident light to the first reflecting surface R11.

The prism P1 is so arranged that an air-equivalent length from incidence positions IP1, IP2 where the rays L1, L2 are incident into the prism P1, to outgoing positions OP1, OP2 where the rays are outgoing from the prism P1 after passage via the mirror elements SE1a, SE1b, is equal to an air-equivalent length from positions corresponding to the incidence positions IP1, IP2 to positions corresponding to the outgoing positions OP1, OP2 with the prism P1 being located outside the exposure apparatus EA1. An air-equivalent length is an optical path length obtained by reducing an optical path length in an optical system to one in air having the refractive index of 1, and an air-equivalent length of an optical path in a medium having the refractive index n is obtained by multiplying an optical path length thereof by 1/n.

The spatial light modulator S1 can be arranged at a position optically equivalent to an installation surface where the diffractive optical elements 2b of the diffractive optical unit 2 are installed, i.e., at the position of the installation surface of the diffractive optical elements 2b observed via the second reflecting surface R12 when viewed from the exit side (zoom optical system 3 side) of the spatial light modulation unit SM1.

The spatial light modulator S1, as shown in FIG. 5, is a movable multi-mirror including the mirror elements SE1 being a large number of micro reflecting elements laid with their reflecting surface of a planar shape up. Each mirror element SE1 is movable and inclination of the reflecting surface thereof, i.e., an angle and direction of inclination of the reflecting surface, is independently driven and controlled by a control system (not shown). Each mirror element SE1 can be continuously rotated by a desired angle of rotation around each of axes of rotation along two directions parallel to the reflecting surface thereof and perpendicular to each other. Namely, concerning each mirror element SE1, inclination thereof can be controlled in two dimensions along its reflecting surface.

The contour of each mirror element SE1 herein is square, but the contour is not limited to it. However, the contour can be such a shape that the mirror elements can be arranged without a space, in terms of efficiency of utilization of light. A gap between adjacent mirror elements SE1 may be set to a necessary minimum space. Furthermore, the mirror elements SE1 may be as small as possible, in order to enable fine change in illumination conditions. The shape of the reflecting surface of each mirror element SE1 is not limited to a plane, but may be a curved surface such as a concave surface or a convex surface.

The optical path extending from the first reflecting surface R11 of the prism P1 to the second reflecting surface R12 of the prism P1 and via a first position where the spatial light modulator S1 of the spatial light modulation unit SM1 can be arranged, is referred to as a first optical path. The optical path extending from the position where the first reflecting surface R11 of the prism P1 can be arranged, to the position where the second reflecting surface R12 of the prism P1 can be arranged, and via a second position where the diffractive optical element 2b of the diffractive optical unit 2 can be arranged, is referred to as a second optical path. The optical path from the light source 1 to the position where the first reflecting surface R11 of the prism P1 can be arranged, is referred to as a third optical path. The optical path from the position where the second reflecting surface R12 of the prism P1 can be arranged, to the illumination target surface, is referred to as a fourth optical path.

Namely, the first optical path is an optical path in which light passes only when the illumination target surface is illuminated with the light from the light source 1 having passed via the spatial light modulator S1. The second optical path is an optical path in which light passes only when the illumination target surface is illuminated with the light from the light source 1 having passed via the diffractive optical element 2b. The third optical path is an optical path between the light source 1 and the first optical path and optical path between the light source 1 and the second optical path. The fourth optical path is an optical path between the first optical path and the illumination target surface and optical path between the second optical path and the illumination target surface. An optical path is a path that is intended for light passage in a use state.

As described above, the spatial light modulation unit SM1 and the diffractive optical unit 2 are so arranged that insertion thereof is switchable from one to the other with respect to the optical axis Ax of the apparatus. Namely, the first optical path and the second optical path are switchable. In addition, the optical axis Ax of the apparatus at the exit of the third optical path and the optical axis Ax of the apparatus at the entrance of the fourth optical path are coaxial.

The first reflecting surface R11 of the prism P1 functions as a first optical surface to direct light from the third optical path toward the spatial light modulator S1, and the second reflecting surface R12 of the prism P1 functions as a second optical surface to direct the light having passed via the spatial light modulator S1, toward the fourth optical path. Since the first and second optical surfaces both are the reflecting surfaces of the prism P1 in the spatial light modulation unit SM1 which can be inserted into or retracted from the optical path of the illumination apparatus IL, the first and second optical surfaces can be integrally inserted into or retracted from the optical path of the illumination apparatus IL. Furthermore, the spatial light modulator S1 can also be inserted into or retracted from the optical path of the illumination apparatus IL.

The first reflecting surface R11 of the prism P1 can be regarded as a first folding surface to fold light incident in parallel with the optical axis, into a direction different from the direction of incidence, and the second reflecting surface R12 of the prism P1 can be regarded as a second folding surface to fold light reflected on the spatial light modulator S1, toward the optical path of the illumination apparatus IL. The first and second folding surfaces can be reflecting surfaces, refracting surfaces, or diffracting surfaces.

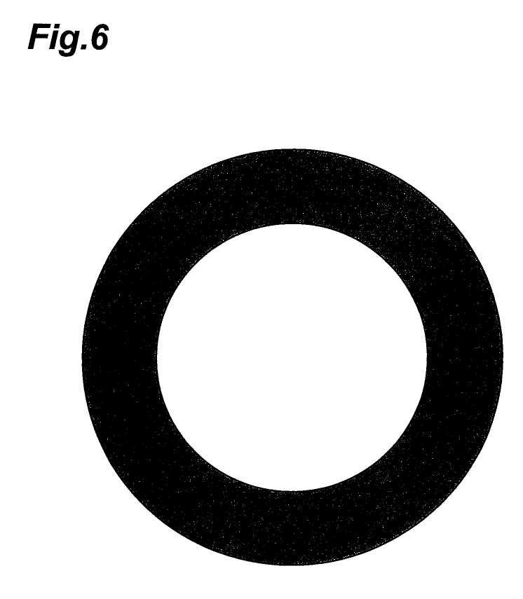

The spatial light modulation unit SM1 enables modified illumination to form a desired pupil luminance distribution, such as circular, annular, dipolar, or quadrupolar illumination. FIG. 6 is a drawing showing a shape of an illumination field in the far field of the spatial light modulation unit SM1 (or on an optical Fourier transform surface for the spatial light modulation unit SM1) in the case of annular illumination. The hatched region in FIG. 6 is the illumination field.

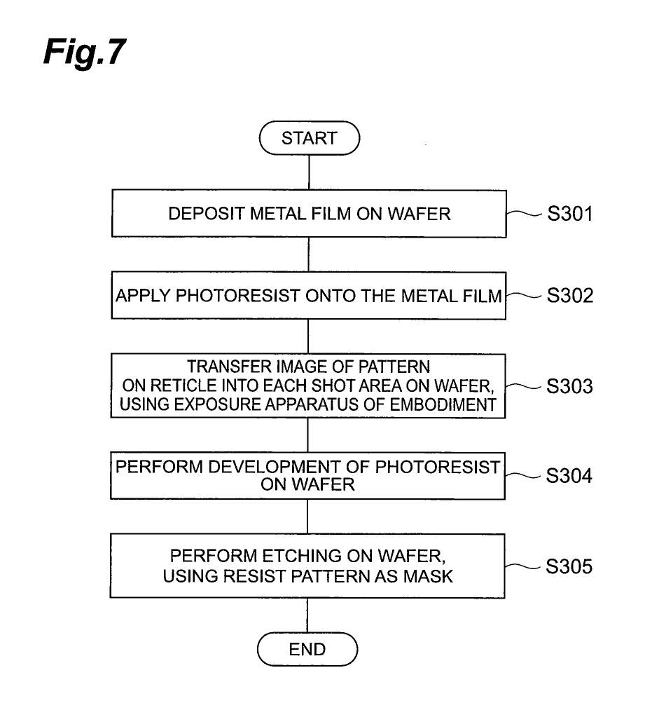

The following will describe a method of manufacturing devices, using the exposure apparatus EA1 of the present embodiment, with reference to the flowchart shown in FIG. 7. The first block S301 in FIG. 7 is to deposit a metal film on each wafer in one lot. The next block S302 is to apply a photoresist onto the metal film on each wafer in the lot. Namely, the blocks S301 and S302 correspond to a block of preparing a wafer W being a photosensitive substrate.

The subsequent block S303 is to sequentially transfer an image of a pattern on a mask M through the projection optical system PL into each shot area on each wafer in the lot, using the exposure apparatus EA1 of the foregoing embodiment.

In the block S303, first, the wafer W is arranged on the wafer stage WS. Light is emitted along the optical axis Ax from the light source 1 to the spatial light modulation unit SM1 or the diffractive optical unit 2. The light is spatially modulated during passage via the spatial light modulation unit SM1 or the diffractive optical unit 2. In the exposure apparatus EA1 the spatial light modulation unit SM1 and the diffractive optical unit 2 can be inserted into or retracted from the optical axis Ax in accordance with the shape of the desired modified illumination.

The light spatially modulated by the spatial light modulation unit SM1 or the diffractive optical unit 2 travels through the zoom optical system 3 to form an illumination field, for example, of a ring circle shape (annular shape) centered on the optical axis Ax, on the entrance surface of the fly's eye lens 4 as an optical integrator of a wavefront division type. The light incident to the fly's eye lens 4 is subjected to wavefront division in the fly's eye lens 4. This results in forming a secondary light source consisting of light source images as many as the lens elements in the fly's eye lens 4, on the rear focal plane thereof.

The light exiting from the fly's eye lens 4 is incident into the condenser optical system 5. The condenser optical system 5 and the fly's eye lens 4 function to uniformly illuminate the pattern surface Ma of the mask M. In this manner, an image of the pattern surface Ma is formed on the projection surface Wa being the surface of the wafer W, based on light from an illumination region formed on the pattern surface Ma of the mask M by the illumination apparatus IL. Thus the image of the pattern surface Ma located on the first surface is projected onto the wafer W arranged on the second surface, to effect exposure thereof.

The subsequent block S304 is to effect development of the photoresist on the wafer in the lot. This block results in forming a mask layer in a shape corresponding to the pattern surface Ma on the projection surface Wa of the wafer W.

Block S305 is to process the projection surface Wa of the wafer W through the mask layer formed in the block S304. Specifically, etching is performed on the wafer in the lot, using the resist pattern as a mask, whereby a circuit pattern corresponding to the pattern on the mask is formed in each shot area on each wafer. Thereafter, devices such as semiconductor devices are manufactured through blocks including formation of circuit patterns in upper layers. The above-described semiconductor device manufacturing method permits us to manufacture the semiconductor devices with extremely fine circuit patterns at high throughput.

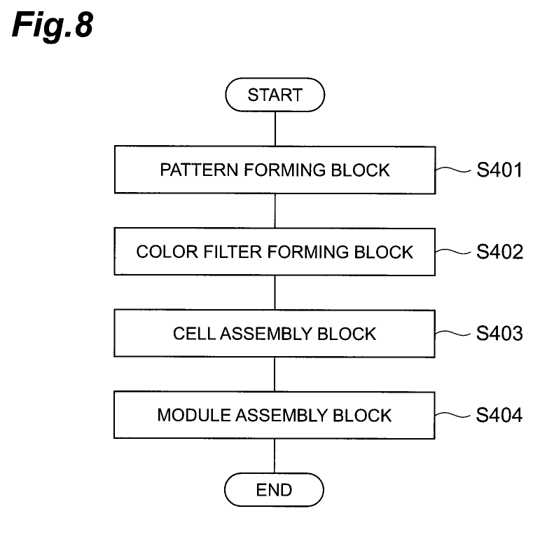

The exposure apparatus of the aforementioned embodiment is also applicable to manufacture of a liquid-crystal display device as a micro device through formation of predetermined patterns (circuit pattern, electrode pattern, etc.) on plates (glass substrates). An example of a method in this case will be described below with reference to the flowchart of FIG. 8. In FIG. 8, a pattern forming block S401 is to execute a so-called photolithography process of transferring a pattern of a mask onto a photosensitive substrate (a glass substrate coated with a resist, or the like) to effect exposure thereof, using the exposure apparatus of the foregoing embodiment. This photolithography process results in forming a predetermined pattern including a large number of electrodes and others on the photosensitive substrate. Thereafter, the exposed substrate is processed through blocks including a development block, an etching block, a resist removal block, and others, whereby the predetermined pattern is formed on the substrate, followed by the next color filter forming block S402.

The next color filter forming block S402 is to form a color filter in which a large number of sets of three dots corresponding to R (Red), G (Green), and B (Blue) are arrayed in a matrix, or in which a plurality of filter sets of three stripes of R, G and B are arrayed in a horizontal scan line direction. After completion of the color filter forming block S402, a cell assembly block S403 is carried out. In the cell assembly block S403, a liquid crystal panel (liquid crystal cell) is assembled using the substrate with the predetermined pattern obtained in the pattern forming block S401, the color filter obtained in the color filter forming block S402, and so on.

In the cell assembly block S403, the liquid crystal panel (liquid crystal cell) is manufactured, for example, by pouring a liquid crystal into between the substrate with the predetermined pattern obtained in the pattern forming block S401 and the color filter obtained in the color filter forming block S402. Thereafter, a module assembly block S404 is carried out to attach such components as electric circuits and backlights for display operation of the assembled liquid crystal panel (liquid crystal cell), thereby completing a liquid-crystal display device. The above-described manufacturing method of the liquid-crystal display device permits us to manufacture the liquid-crystal display device with extremely fine circuit patterns at high throughput. The present embodiment is not limited to the application to the manufacturing processes of semiconductor devices and liquid-crystal display devices, but can also be widely applied, for example, to manufacturing processes of plasma displays and others, and manufacturing processes of various devices such as micromachines, MEMS (Microelectromechanical Systems), thin-film magnetic heads, DNA chips, and so on.

The spatial light modulator S1 of the spatial light modulation unit SM1 applies the spatial modulation to the light, according to the position where the light is incident. For this reason, it is able to form a desired pupil luminance distribution, e.g., a dipolar, quadrupolar, annular, or other distribution.

The spatial light modulation unit SM1 has the first and second reflecting surfaces R11, R12 in addition to the spatial light modulator S1. For this reason, it can be arranged in the optical system so as to form a desired optical path.

The spatial light modulator S1 in the exposure apparatus EA1 of the present embodiment modulates the light so that the optical path of the light reflected on the second reflecting surface R12 to be emitted from the spatial light modulation unit SM1 into the zoom optical system 3 coincides with the optical path of the incident light to the first reflecting surface R11. Namely, the optical path of the light incident to the spatial light modulation unit SM1 is coincident with the optical path of the light exiting from the spatial light modulation unit SM1. For this reason, there is no change in the optical path in the case where the spatial light modulation unit SM1 is inserted, or in the case where the diffractive optical unit 2 is inserted, whereby the spatial light modulation unit SM1 can be freely inserted into or retracted from the optical axis Ax of the exposure apparatus EA1.

Particularly, there is no change in the air-equivalent length of light passing through the optical path between in the case where the spatial light modulation unit SM1 is inserted and in the case where the spatial light modulation unit SM1 is located off the optical axis Ax. For this reason, the exposure apparatus EA1 permits the spatial light modulation unit SM1 to be inserted or retracted without any change in the configuration.

Since the optical path on the exit side is coincident with that on the entrance side of the spatial light modulation unit SM1, the configuration of the illumination apparatus IL using the spatial light modulation unit SM1 can be shared with the illumination optical system using the diffractive optical unit 2. This permits reduction in cost.

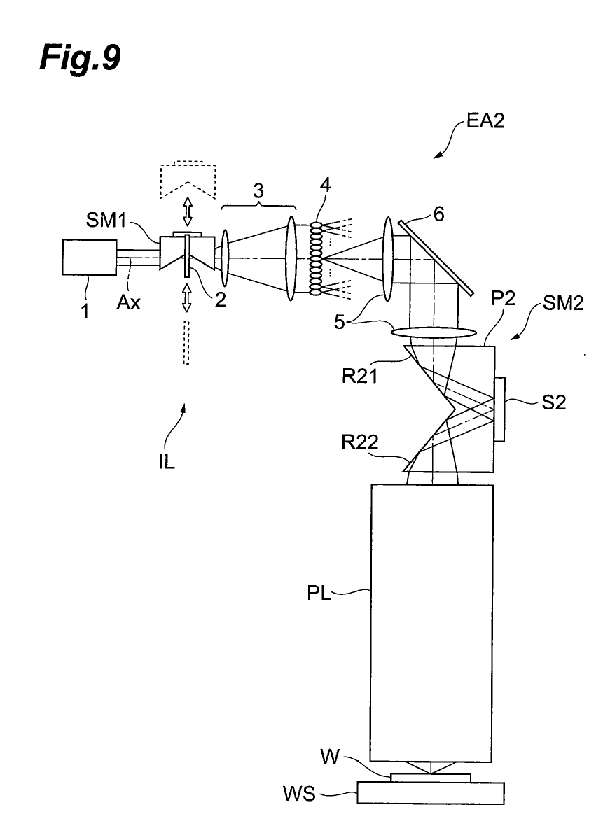

FIG. 9 shows a schematic configuration diagram of a maskless exposure apparatus EA2 being a modification example of the exposure apparatus EA1 according to the first embodiment. The exposure apparatus EA2 of the modification example is different from the exposure apparatus EA1 of the first embodiment, in that it has a spatial light modulation unit SM2 instead of the mask.

The spatial light modulation unit SM2, similar to the spatial light modulation unit SM1, has first and second reflecting surfaces R21, R22, and a spatial light modulator S2. The illumination apparatus IL of the exposure apparatus EA2 illuminates a reflecting surface (first surface) of the spatial light modulator S2 in the spatial light modulation unit SM2. The projection optical system PL forms an image of the first surface on the projection surface Wa (second surface) on the wafer W, based on light from an illumination region formed on the reflecting surface (first surface) of the spatial light modulator S2 by the illumination apparatus IL.

### Second Embodiment

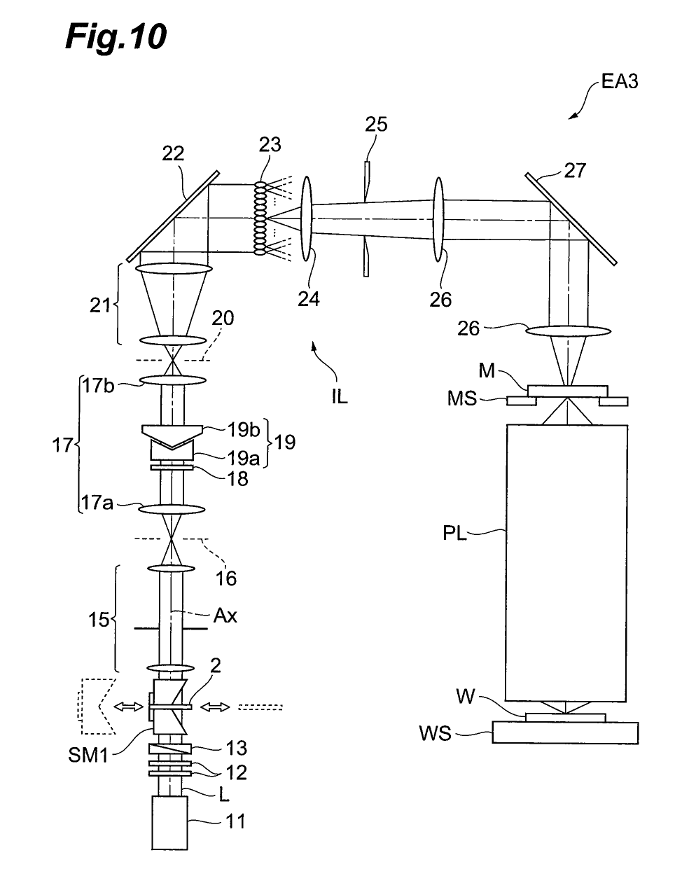

A configuration of an exposure apparatus EA3 according to the second embodiment will be described with reference to FIG. 10. FIG. 10 is a configuration diagram schematically showing the exposure apparatus of the second embodiment.

The exposure apparatus EA3 of the second embodiment has a light source 11, an illumination apparatus IL provided with a spatial light modulation unit SM1, a mask stage MS supporting a mask M, a projection optical system PL, and a wafer stage WS supporting a wafer W, along the optical axis Ax of the apparatus.

The illumination apparatus IL has a polarization state control unit 12, a depolarizer 13 which can be inserted into or retracted from the optical path of the illumination apparatus IL, a spatial light modulation unit SM1, a diffractive optical unit 2, a relay optical system 15, an afocal optical system 17, a polarization converting element 18, a conical axicon system 19, a zoom optical system 21, a folding mirror 22, a micro fly's eye lens 23, a condenser optical system 24, an illumination field stop (mask blind) 25, an imaging optical system 26, and a folding mirror 27 along the optical axis Ax. Each of the spatial light modulation unit SM1 and the diffractive optical unit 2 to form a desired pupil luminance distribution, can be inserted into or retracted from the optical path of the illumination apparatus IL.

A nearly parallel beam emitted from the light source 11 travels through the polarization state control unit 12 having a quarter wave plate and a half wave plate rotatable around the optical axis Ax, to be converted into a light beam in a predetermined polarization state, and the beam then travels via the spatial light modulation unit SM1 or the diffractive optical unit 2 and through the relay optical system 15 to enter the afocal optical system 17. In a case where the mask M is illuminated with light in an unpolarized state, the beam from the light source 11 having passed through the polarization state control unit 12 travels through the depolarizer 13 inserted in the optical path of the illumination apparatus IL and then enters the spatial light modulation unit SM1 or the diffractive optical unit 2. Concerning such polarization state control unit 12 and depolarizer 13, reference can be made to U.S. Pat. Published Application No. 2006/0170901A1. U.S. Pat. Published Application No. 2006/0170901A1 is incorporated as references herein.

The afocal optical system 17 is an afocal system (afocal optic) so set that the front focal position thereof is approximately coincident with a position of a predetermined plane 16 indicated by a dashed line in the drawing and that the rear focal position thereof is approximately coincident with a position of a predetermined plane 20 indicated by a dashed line in the drawing. On the other hand, the spatial light modulation unit SM1 or the diffractive optical unit 2 is arranged at a position conjugate with the position of the predetermined plane 16, as indicated by dashed lines in the drawing.

Therefore, the nearly parallel beam incident to the spatial light modulation unit SM1 or the diffractive optical unit 2 as a beam converting element forms, for example, an annular light intensity distribution on the pupil plane of the afocal optical system 17 as a relay optical system and thereafter is emitted as a nearly parallel beam from the afocal optical system 17. The polarization converting element 18 and the conical axicon system 19 are arranged at or near the pupil position of the afocal optical system in the optical path between a front lens unit 17a and a rear lens unit 17b of the afocal optical system 17.

The conical axicon system 19 is composed of the following members arranged in the order named from the light source side: a first prism member 19a with a plane on the light source side and a refracting surface of a concave conical shape on the mask side; and a second prism member 19b with a plane on the mask side and a refracting surface of a convex conical shape on the light source side. The refracting surface of the concave conical shape of the first prism member 19a and the refracting surface of the convex conical shape of the second prism member 19b are complementarily formed so that they can contact each other. At least one of the first prism member 19a and the second prism member 19b is configured to be movable along the optical axis Ax so as to make the spacing variable between the refracting surface of the concave conical shape of the first prism member 19a and the refracting surface of the convex conical shape of the second prism member 19b. By the action of the conical axicon system 19, the annular ratio (inside diameter/outside diameter) and size (outside diameter) of the annular secondary light source both vary, without change in the width of the secondary light source.

When the concave conical refracting surface of the first prism member 19a contacts the convex conical refracting surface of the second prism member 19b, the conical axicon system 19 functions as a plane-parallel plate and causes no effect on the annular secondary light source formed. However, when the concave conical refracting surface of the first prism member 19a is separated from the convex conical refracting surface of the second prism member 19b, the conical axicon system 19 functions as a so-called beam expander. Therefore, the angle of the incident beam to the predetermined plane 20 varies according to change in the spacing of the conical axicon system 19.

The polarization converting element 18 has a function to convert incident light in a linearly polarized state, into light in a circumferentially polarized state with the polarization direction approximately along the circumferential direction or into light in a radially polarized state with the polarization direction approximately along a radial direction. Concerning such polarization converting element 18, reference can be made to the aforementioned U.S. Pat. Published Application No. 2006/0170901A1. U.S. Pat. Published Application No. 2006/0170901A1 is incorporated as references herein.

The beam having passed through the afocal optical system 17 travels via the zoom optical system 21 for variation in a value and the folding mirror 22 to enter the micro fly's eye lens (or fly's eye lens) 23 as an optical integrator. The micro fly's eye lens 23 is an optical element consisting of a large number of micro lenses with a positive refracting power arranged vertically and horizontally and densely. In general, a micro fly's eye lens is made, for example, by forming the micro lens group by etching of a plane-parallel plate.

Each micro lens forming the micro fly's eye lens is smaller than each lens element forming a fly's eye lens. The micro fly's eye lens is different from the fly's eye lens consisting of lens elements isolated from each other, in that a large number of micro lenses (micro refracting faces) are integrally formed without being isolated from each other. However, the micro fly's eye lens is an optical integrator of the same wavefront division type as the fly's eye lens, in that the lens elements with the positive refracting power are arranged horizontally and vertically.

The position of the predetermined plane 20 is located near the front focal position of the zoom optical system 21 and the entrance surface of the micro fly's eye lens 23 is located near the rear focal position of the zoom optical system 21. By the action of the zoom optical system 21, the width and size (outside diameter) of the annular secondary light source both vary, without change in the annular ratio of the annular secondary light source. The zoom optical system 21 keeps the predetermined plane 20 and the entrance surface of the micro fly's eye lens 23 substantially in the relation of Fourier transform and, in turn, keeps the pupil plane of the afocal optical system 17 and the entrance surface of the micro fly's eye lens 23 approximately optically conjugate with each other.

Therefore, for example, an annular illumination field centered on the optical axis Ax is formed on the entrance surface of the micro fly's eye lens 23 as on the pupil plane of the afocal optical system 17. The overall shape of this annular illumination field varies similarly depending upon the focal length of the zoom optical system 21. Each micro lens forming the micro fly's eye lens 23 has a cross section of a rectangular shape similar to a shape of an illumination field to be formed on the mask M (and thus to a shape of an exposure region to be formed on the wafer W).

The beam incident to the micro fly's eye lens 23 is two-dimensionally divided by the large number of micro lenses and a secondary light source with a light intensity distribution approximately equal to the illumination field formed by the incident beam, i.e., a secondary light source consisting of a substantial surface illuminant of an annular shape centered on the optical axis Ax is formed on or near the rear focal plane of the micro fly's eye lens 23 (and, therefore, on the illumination pupil plane). Beams from the secondary light source formed on or near the rear focal plane of the micro fly's eye lens 23 travel through the condenser optical system 24 to superposedly illuminate the mask blind 25.

In this manner, the illumination field of the rectangular shape according to the shape and focal length of each micro lens forming the micro fly's eye lens 23 is formed on the mask blind 25 as an illumination field stop. The beams having passed through a rectangular aperture (light transmitting portion) of the mask blind 25 are subjected to converging action of the imaging optical system 26, to superposedly illuminate the mask M with the predetermined pattern formed therein. Namely, the imaging optical system 26 forms an image of the rectangular aperture of the mask blind 25 on the mask M.

A beam transmitted by a pattern of the mask M held on the mask stage MS travels through the projection optical system PL to form an image of the mask pattern on the wafer (photosensitive substrate) W held on the wafer stage WS. In this manner, the pattern of the mask M is sequentially transferred into each of exposure areas on the wafer W by performing one-shot exposure or scanning exposure while two-dimensionally driving and controlling the wafer stage WS in the plane perpendicular to the optical axis Ax of the projection optical system PL and, therefore, while two-dimensionally driving and controlling the wafer W.

The afocal optical system (relay optical system) 17, the conical axicon system 19, and the zoom optical system (power-varying optical system) 21 constitute a shaping optical system for changing the size and shape of the secondary light source (substantial surface illuminant) formed on the illumination pupil plane, which is arranged in the optical path between the spatial light modulation unit SM1 or the diffractive optical unit 2 and the micro fly's eye lens (optical integrator) 23.

The spatial light modulation unit SM1 is arranged so as to be switchable with the diffractive optical unit 2 in FIG. 10, but it may be arranged, for example, on the plane 16 indicated by the dashed line in FIG. 10. The position of the plane 16 corresponds to a position optically conjugate with the position of the diffractive optical unit 2.

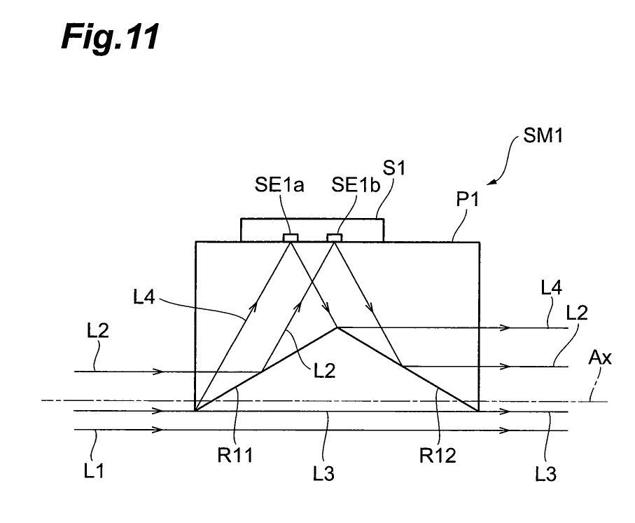

In this case, as shown in FIG. 11, the spatial light modulation unit SM1 may be arranged on the optical axis Ax so that only part of the beam emitted from the light source 11 passes through the unit. In the spatial light modulation unit SM1 shown in FIG. 11, when compared, for example, with the arrangement as shown in FIG. 4, the spatial light modulator S1 is arranged as moved to the light source 11 side relative to the first and second reflecting surfaces R11, R12, in the direction along the optical axis Ax. In this arrangement, for example, rays L1, L3 in the light beam emitted from the light source 11 are incident to the afocal optical system 17, without entering the interior of the prism P1 in the spatial light modulation unit SM1. On the other hand, rays L2 and L4 in the beam emitted from the light source 11 are incident into the prism P1 of the spatial light modulation unit SM1, are reflected on the first reflecting surface R11, the spatial light modulator S1, and the second reflecting surface R12, and thereafter exite from the prism P1 to enter the afocal optical system 17.

In this case, the spatial light modulator S1 can be fixed, for example, at the position of the plane 16 indicated by the dashed line in FIG. 10. Then, as apparent from FIG. 11, it is possible to simultaneously use the first optical path being an optical path from the first reflecting surface R11 of the prism P1 to the second reflecting surface R12 of the prism P1 and optical path extending via the first position where the spatial light modulator S1 can be arranged, and the second optical path being an optical path from the position where the first reflecting surface R11 of the prism P1 can be arranged, to the position where the second reflecting surface R12 of the prism P1 can be arranged, in the case where the spatial light modulation unit SM1 is arranged at the position of the plane 16 so as to be switchable with the diffractive optical unit 2, and optical path in which the diffractive optical element 2b of the diffractive optical unit 2 can be arranged. In this case, the optical path from the light source 11 to the position where the first reflecting surface R11 of the prism P1 can be arranged functions as a third optical path. The optical path from the position where the second reflecting surface R12 of the prism P1 can be arranged to the illumination target surface in the case where the spatial light modulation unit SM1 is arranged at the position of the plane 16 so as to be switchable with the diffractive optical unit 2, functions as a fourth optical path.

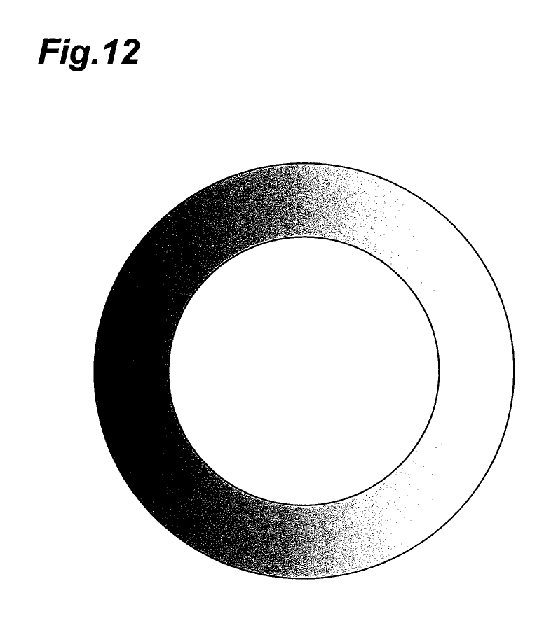

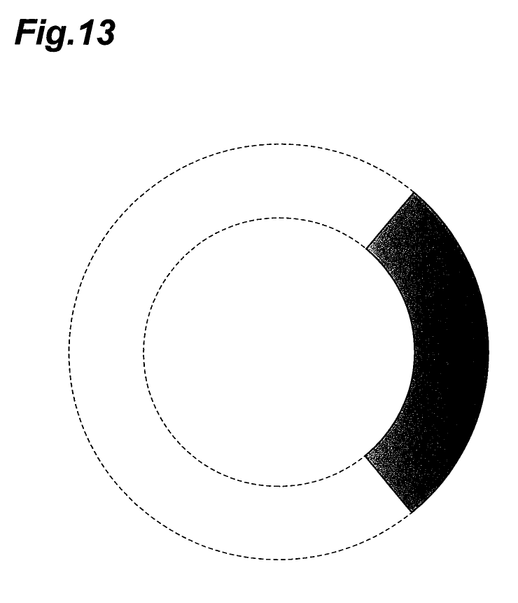

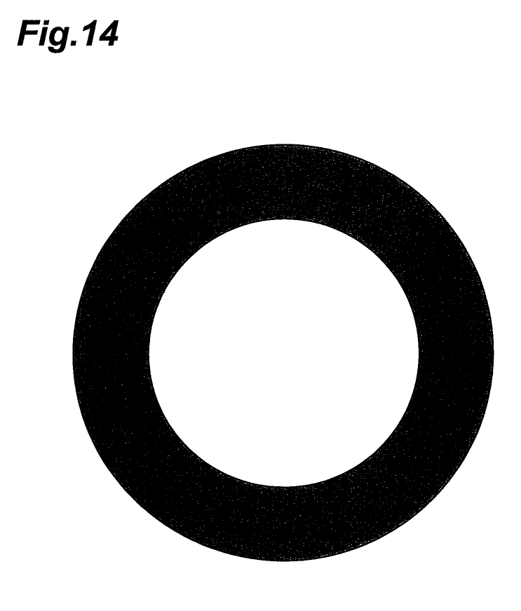

When the spatial light modulation unit SM1 is arranged at the position of the predetermined plane 16 and configured to reflect only part of the beam by the spatial light modulator S1 of the spatial light modulation unit SM1 as shown in FIG. 11, it becomes feasible, for example, to make a correction for pupil intensity as shown in FIGS. 12-14. FIG. 12 shows a pupil luminance distribution formed by a beam passing the diffractive optical unit 2 but not passing the spatial light modulation unit SM1. FIG. 13 shows a pupil luminance distribution formed by a beam not passing the diffractive optical unit 2 but passing the spatial light modulation unit SM1. FIG. 14 shows a pupil luminance distribution obtained by superposing the pupil luminance distribution of FIG. 12 on the pupil luminance distribution of FIG. 13. Shades in FIGS. 12-14 indicate levels of luminance on the pupil plane (the darker the shade, the higher the luminance).

Specifically, the diffractive optical unit 2 forms the first pupil luminance distribution in which the luminance decreases from left to right on the plane of the drawing, as shown in FIG. 12, with the light not passing the spatial light modulator S1 of the spatial light modulation unit SM1. On the other hand, the spatial light modulator S1 of the spatial light modulation unit SM1 forms the second pupil luminance distribution with high and approximately even luminance, which overlaps at least in part with the first pupil luminance distribution, as shown in FIG. 13. An overall almost even pupil luminance distribution can be obtained by superposing the first pupil luminance distribution with uneven luminance on the second pupil luminance distribution to strengthen the low luminance part in the first pupil luminance distribution as shown in FIG. 14. The above-described example concerned generation of the overall almost even pupil luminance distribution, but the pupil luminance distribution to be generated is not limited to the almost even, distribution. As an example, it is also possible to change the pupil luminance distribution into an uneven distribution in order to adjust a transfer state of the pattern of the mask M.

In the spatial light modulation unit SM1, there is no change in the air-equivalent length of light passing in the optical path between in the case where the spatial light modulation unit SM1 is inserted and in the case where the spatial light modulation unit SM1 is retracted from the optical axis Ax. For this reason, the air-equivalent length of the rays L1, L3 is equal to that of the rays L2, L4, and it is thus easy to combine and handle the rays passing the spatial light modulation unit SM1 and the rays not passing it.

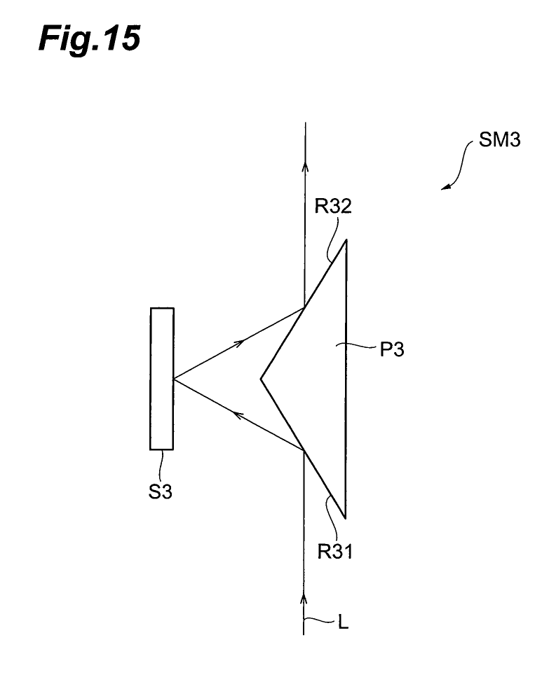

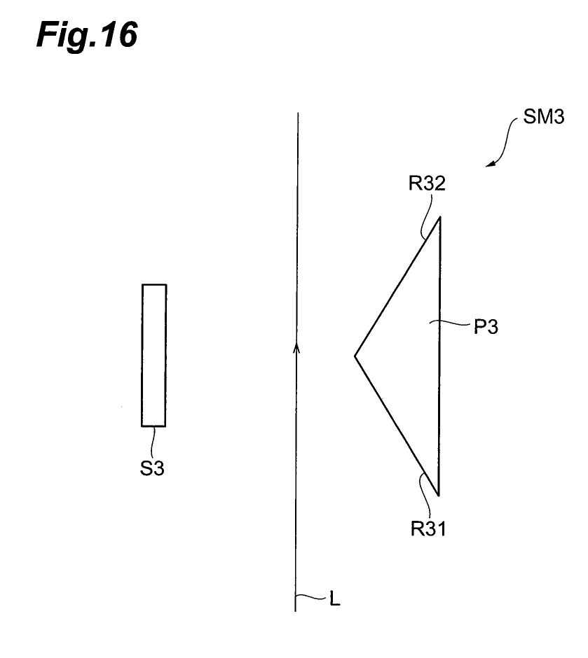

In the case where the spatial light modulation unit SM1 is inserted at the position of the predetermined plane 16, it is also possible to use another spatial light modulation unit SM3, for example, based on the configuration shown in FIGS. 15 and 16. FIG. 15 is a drawing showing the arrangement in the case where the spatial light modulation unit SM3 is arranged so that first and second reflecting surfaces R31, R32 of the spatial light modulation unit SM3 intersect with the optical axis Ax. FIG. 16 is a drawing showing the arrangement in the case where the spatial light modulation unit SM3 is arranged so that the first and second reflecting surfaces R31, R32 of the spatial light modulation unit SM3 do not intersect with the optical axis Ax.

The spatial light modulation unit SM3 has a V-shaped prism (reflecting member) P3 and a spatial light modulator S3. The spatial light modulator S3 is not constructed integrally with the prism P3, different from the spatial light modulation unit SM1.

A pair of surface-reflecting surfaces provided on the prism P3 and adjoining at a predetermined angle being an obtuse angle correspond to the first and second reflecting surfaces R31, R32. The positional relationship between the prism P3 and the spatial light modulator S3 can be relatively changed in a direction intersecting with the optical axis Ax, as shown in FIGS. 15 and 16. Namely, the prism P3 is moved to make the first and second reflecting surfaces R31, R32 intersect with the optical axis Ax, while keeping the spatial light modulator S3 fixed.

The spatial light modulator S1 in the exposure apparatus EA3 according to the present embodiment modulates the light so that the optical path of the light reflected on the second reflecting surface R12 to be emitted toward the relay optical system 15 in the spatial light modulation unit SM1 is coincident with the optical path of the incident light to the first reflecting surface R11. Namely, the optical path of the light incident to the spatial light modulation unit SM1 is coincident with the optical path of the light exiting from the spatial light modulation unit SM1. For this reason, there is no change in the optical path in the case where the spatial light modulation unit SM1 is inserted, or in the case where the diffractive optical unit 2 is inserted, whereby the spatial light modulation unit SM1 can be freely inserted into or retracted from the optical axis Ax of the exposure apparatus EA3.

Since the optical path of the light incident to the spatial light modulation unit SM1 is coincident with the optical path of the light exiting from the spatial light modulation unit SM1, the spatial light modulation unit SM1 can be inserted into or retracted from the position of the predetermined plane 16, without significant change in the configuration of the illumination apparatus IL.

Particularly, there is no change in the air-equivalent length of light passing in the optical path between in the case where the spatial light modulation unit SM1 is inserted and in the case where the spatial light modulation unit SM1 is located off the optical axis Ax. In the exposure apparatus EA3, therefore, the spatial light modulation unit SM1 can be inserted and retracted without any change in the configuration of the illumination apparatus IL.

Since the optical path on the exit side can be made coincident with that on the entrance side of the spatial light modulation unit SM1, the configuration of the illumination apparatus IL using the spatial light modulation unit SM1 can be shared with the illumination optical system using the diffractive optical unit 2. This permits reduction in cost.

Thus, an embodiment of the present invention successfully can provide the spatial light modulation unit that can be arranged in an optical system so as to form a desired light path.

The above described the embodiments of the present invention, but it is noted that the present invention is not limited to the above embodiments but can be modified in many ways. In the above embodiments, for example, the spatial light modulator with the plurality of reflecting elements arranged two-dimensionally and controlled individually was, for example, the spatial light modulator in which inclinations of the reflecting surfaces arranged two-dimensionally could be controlled individually. The spatial light modulator of this type can be one selected from those disclosed, for example, in Japanese Patent Application Laid-open (Translation of PCT Application) No. 10-503300 and European Patent Application Publication EP779530 corresponding thereto, Japanese Patent Application Laid-open No. 2004-78136 and U.S. Pat. No. 6,900,915 corresponding thereto, Japanese Patent Application Laid-open (Translation of PCT Application) No. 2006-524349 and U.S. Pat. No. 7,095,546 corresponding thereto, and Japanese Patent Application Laid-open No. 2006-113437. In these spatial light modulators, light beams having passed via the individual reflecting surfaces of the spatial light modulator are incident at predetermined angles to the distribution forming optical system and a predetermined light intensity distribution according to control signals to the plurality of optical elements can be formed on the illumination pupil plane. European Patent Application Publication EP779530, U.S. Pat. No. 6,900,915, and U.S. Pat. No. 7,095,546 are incorporated as references herein.

The spatial light modulator can also be, for example, one in which heights of the reflecting surfaces arranged two-dimensionally can be controlled individually. The spatial light modulator of this type can be one selected from those disclosed, for example, in Japanese Patent Application Laid-open No. 6-281869 and U.S. Pat. No. 5,312,513 corresponding thereto, and in FIG. 1d in Japanese Patent Application Laid-open (Translation of PCT Application) No. 2004-520618 and U.S. Pat. No. 6,885,493 corresponding thereto. These spatial light modulators can apply the same action as diffracting surfaces to the incident light when a two-dimensional height distribution is formed. U.S. Pat. No. 5,312,513 and U.S. Pat. No. 6,885,493 are incorporated as references herein.

The above-described spatial light modulator with the plurality of reflecting surfaces arranged two-dimensionally may be modified, for example, according to the disclosure in Japanese Patent Application Laid-open (Translation of PCT Application) No. 2006-513442 and U.S. Pat. No. 6,891,655 corresponding thereto or the disclosure in Japanese Patent Application Laid-open (Translation of PCT Application) No. 2005-524112 and U.S. Pat. Published Application No. 2005/0095749 corresponding thereto. U.S. Pat. No. 6,891,655 and U.S. Pat. Published Application No. 2005/0095749 are incorporated as references herein.

The air-equivalent length of light passing through the optical unit in the case where the spatial light modulation unit SM1, SM2 is inserted may be made different from that of light passing in the optical path in the case where the spatial light modulation unit SM1, SM2 is located off the optical axis Ax. The shape of the prism P1, P2 in the spatial light modulation unit SM1, SM2 is not limited to that shown in the embodiments and modification example.

It is also possible to provide a pupil luminance distribution measuring device for measuring the pupil luminance distribution formed by the spatial light modulation unit SM1, SM2, in the illumination apparatus IL or in the exposure apparatus EA1, EA2, EA3. Reference can be made, for example, to Japanese Patent Application Laid-open No. 2006-54328 about the configuration in which the pupil luminance distribution measuring device is incorporated in the illumination apparatus IL, and reference can be made, for example, to U.S. Pat. Published Application No. 2006/0170901A1 about the configuration in which the pupil luminance distribution measuring device is incorporated in the exposure apparatus EA1, EA2, EA3. For adjusting the pupil luminance distribution formed by the spatial light modulation unit SM1, SM2, to a desired pupil luminance distribution, based on the result of the measurement by such a pupil luminance distribution measuring device, it is also possible to correct the drive signals to the spatial light modulation unit SM1, SM2.

In the above-described embodiments, the light source 1, 11 can be, for example, an ArF excimer laser light source which supplies pulsed laser light at the wavelength of 193 nm, or a KrF excimer laser light source which supplies pulsed laser light at the wavelength of 248 nm. Without having to be limited to these, it is also possible, for example, to use another appropriate light source such as an F₂ laser light source or an ultrahigh pressure mercury lamp. The above-described embodiments showed the application of the present invention to the scanning exposure apparatus, but, without having to be limited to it, the present invention can also be applied to exposure apparatus of the one-shot exposure type performing projection exposure in a state in which the reticle (mask) and wafer (photosensitive substrate) are stationary relative to the projection optical system.

In the foregoing embodiments, it is also possible to apply a technique of filling the interior of the optical path between the projection optical system and the photosensitive substrate with a medium having the refractive index larger than 1.1 (typically, a liquid), which is so called a liquid immersion method. In this case, it is possible to adopt one of the following techniques as a technique of filing the interior of the optical path between the projection optical system and the photosensitive substrate with the liquid: the technique of locally filling the optical path with the liquid as disclosed in International Publication WO99/49504; the technique of moving a stage holding the substrate to be exposed, in a liquid bath as disclosed in Japanese Patent Application Laid-open No. 6-124873; the technique of forming a liquid bath of a predetermined depth on a stage and holding the substrate therein as disclosed in Japanese Patent Application Laid-open No. 10-303114, and so on. International Publication WO99/49504, Japanese Patent Application Laid-open No. 6-124873, and Japanese Patent Application Laid-open No. 10-303114 are incorporated as references herein.

In the foregoing embodiment, it is also possible to apply the so-called polarized illumination method disclosed in U.S Pat. Published Application Nos. 2006/0203214, 2006/0170901, and 2007/0146676. Teachings of the U.S Pat. Published Application Nos. 2006/0203214, 2006/0170901, and 2007/0146676 are incorporated herein by reference.

The present invention is not limited to the above-described embodiments but can be carried out in various configurations without departing from the spirit and scope of the present invention.

The invention is not limited to the fore going embodiments but various changes and modifications of its components may be made without departing from the scope of the present invention. Also, the components disclosed in the embodiments may be assembled in any combination for embodying the present invention. For example, some of the components may be omitted from all components disclosed in the embodiments. Further, components in different embodiments may be appropriately combined.

What is claimed is:

1. A spatial light modulation unit which can be arranged in an optical system and which can be arranged along an optical axis of the optical system, the spatial light modulation unit comprising:
a first folding surface to fold light incident in parallel with the optical axis of the optical system;
a reflective spatial light modulator to reflect the light folded on the first folding surface; and
a second folding surface to fold the light reflected on the spatial light modulator, and to send forth the light into the optical system;
wherein the spatial light modulator applies spatial modulation to the light, according to a position where the light folded on the first folding surface is incident to the spatial light modulator.

2. The spatial light modulation unit according to claim 1, wherein the second folding surface includes a reflecting surface.

3. The spatial light modulation unit according to claim 2, wherein the first folding surface includes a reflecting surface.

4. The spatial light modulation unit according to claim 3, wherein the first and second folding surfaces include their respective internal reflecting surfaces.

5. The spatial light modulation unit according to claim 4, wherein the first and second reflecting surfaces are reflecting surfaces of a prism and wherein the spatial light modulator is attached integrally to the prism.

6. The spatial light modulation unit according to claim 4, wherein an air-equivalent length from a position of incidence to the prism to a exiting position from the prism is equal to an air-equivalent length from a position corresponding to the position of incidence to a position corresponding to the exiting position in a case where the prism is arranged outside the optical system.

7. The spatial light modulation unit according to claim 1, wherein the spatial light modulator is relatively movable relative to the first and second folding surfaces, in a direction along the optical axis of the optical system.

8. The spatial light modulation unit according to claim 3, wherein the first and second folding surfaces include their respective surface-reflecting surfaces.

9. The spatial light modulation unit according to claim 6, wherein the first and second folding surfaces are a pair of reflecting surfaces provided at a predetermined angle on a reflecting member.

10. The spatial light modulation unit according to claim 9, wherein the reflecting member and the spatial light modulator are arranged in a positional relation that can be relatively changed in a direction intersecting with the optical axis of the optical system.

11. The spatial light modulation unit according to claim 1, wherein the first and second folding surfaces and the spatial light modulator are arranged in a positional relation that can be relatively changed in a direction intersecting with the optical axis of the optical system.

12. The spatial light modulation unit according to claim 1, wherein the spatial light modulator includes a plurality of reflecting elements arranged two-dimensionally, and
wherein the plurality of reflecting elements can be controlled independently of each other.

13. The spatial light modulation unit according to claim 12, wherein each of the plurality of reflecting elements of the spatial light modulator includes a reflecting surface, and
wherein inclinations of the reflecting surfaces of the reflecting elements can be controlled independently.

14. The spatial light modulation unit according to claim 13, wherein the spatial light modulator can modulate the light so that the light folded on the second folding surface to be emitted into the optical system becomes parallel to the incident light to the first folding surface.

15. A spatial light modulation unit which can be arranged in an optical system and which can be arranged along an optical axis of the optical system, the spatial light modulation unit comprising:
a first reflecting surface obliquely arranged relative to the optical axis of the optical system;
a second reflecting surface obliquely arranged relative to the optical axis of the optical system; and
a spatial light modulator provided so that it can be arranged in an optical path between the first reflecting surface and the second reflecting surface;
wherein the spatial light modulator applies spatial modulation to the light, according to a position in the spatial light modulator where the light is incident to the spatial light modulator.

16. The spatial light modulation unit according to claim 15, wherein the first reflecting surface is located on a first plane, and
wherein the second reflecting surface is located on a second plane intersecting with the first plane.

17. The spatial light modulation unit according to claim 16, wherein a ridge line made by the first and second planes is located on the spatial light modulator side with respect to the first and second reflecting surfaces and wherein an angle between the first and second reflecting surfaces is an obtuse angle.

18. An illumination apparatus which illuminates a first surface with light supplied from a light source, the illumination apparatus comprising:
the spatial light modulation unit as set forth in claim 1.

19. The illumination apparatus according to claim 18, further comprising a diffractive optical element to form a desired pupil luminance distribution,
wherein the spatial light modulator can be arranged at a position conjugate with the diffractive optical element.

20. The illumination apparatus according to claim 18, further comprising a diffractive optical element which forms a desired pupil luminance distribution and which can be installed on a predetermined installation surface,
wherein the spatial light modulator can be arranged at a position optically equivalent to the predetermined installation surface.

21. The illumination apparatus according to claim 20, wherein the diffractive optical element can be inserted into or retracted from an optical path of the illumination apparatus.

22. An illumination apparatus which illuminates a first surface with light supplied from a light source, the illumination apparatus comprising:
the spatial light modulation unit as set forth in claim 15.

23. The illumination apparatus according to claim 22, further comprising a diffractive optical element to form a desired pupil luminance distribution,
wherein the spatial light modulator can be arranged at a position conjugate with the diffractive optical element.

24. The illumination apparatus according to claim 22, further comprising a diffractive optical element which forms a desired pupil luminance distribution and which can be installed on a predetermined installation surface,
wherein the spatial light modulator can be arranged at a position optically equivalent to the predetermined installation surface.

25. The illumination apparatus according to claim 23, wherein the diffractive optical element can be inserted into or retracted from an optical path of the illumination apparatus.

26. An illumination apparatus which illuminates an illumination target surface on the basis of light from a light source, the illumination apparatus comprising:
a spatial light modulator including a plurality of optical elements arranged two-dimensionally and controlled individually;
a diffractive optical element which can be arranged in the illumination apparatus;
a first optical path in which the spatial light modulator can be arranged at a first position thereof;
a second optical path in which the diffractive optical element can be arranged at a second position thereof;
a third optical path which is an optical path between the light source and the first optical path and optical path between the light source and the second optical path; and
a fourth optical path which is an optical path between the first optical path and the illumination target surface and optical path between the second optical path and the illumination target surface;
wherein the first optical path and the second optical path are switchable from one to the other and wherein an optical axis at an exit of the third optical path and an optical axis at an entrance of the fourth optical path are coaxial.

27. The illumination apparatus according to claim 26, comprising: a first optical surface which directs light from the third optical path toward the spatial light modulator; and a second optical surface which directs light having passed via the spatial light modulator, toward the fourth optical path.

28. The illumination apparatus according to claim 27, wherein the first optical surface and the second optical surface can be inserted into or retracted from an optical path of the illumination apparatus.

29. The illumination apparatus according to claim 28, wherein the first and second optical surfaces can be integrally inserted into or retracted from the optical path of the illumination apparatus.

30. The illumination apparatus according to claim 26, wherein the spatial light modulator can be inserted into or retracted from an optical path of the illumination apparatus.

31. The illumination apparatus according to claim 26, wherein the spatial light modulator is fixed at a predetermined position.

32. The illumination apparatus according to claim 26, wherein the first optical path and the second optical path are simultaneously used.

33. The illumination apparatus according to claim 27, wherein the first and second optical surfaces include their respective reflecting surfaces.

34. The illumination apparatus according to claim 26, wherein the spatial light modulator includes a plurality of reflecting elements arranged two-dimensionally, and
wherein the plurality of reflecting elements can be controlled independently of each other.

35. The illumination apparatus according to claim 34, wherein each of the reflecting elements of the spatial light modulator includes a reflecting surface, and
wherein inclinations of the reflecting surfaces of the reflecting elements can be controlled independently.

36. An exposure apparatus which projects an image of a first surface onto a second surface, the exposure apparatus comprising:
the illumination apparatus as set forth in claim 18, which illuminates the first surface; and
a projection optical system which forms the image of the first surface on the second surface, based on light from an illumination region formed on the first surface by the illumination apparatus.

37. An exposure apparatus which projects an image of a first surface onto a second surface, the exposure apparatus comprising:
the illumination apparatus as set forth in claim 22, which illuminates the first surface; and
a projection optical system which forms the image of the first surface on the second surface, based on light from an illumination region formed on the first surface by the illumination apparatus.

38. An exposure apparatus which projects an image of a first surface onto a second surface, the exposure apparatus comprising:
the illumination apparatus as set forth in claim 26, which illuminates the first surface; and
a projection optical system which forms the image of the first surface on the second surface, based on light from an illumination region formed on the first surface by the illumination apparatus.

39. An exposure apparatus which projects an image of a first surface onto a second surface, the exposure apparatus comprising:
an illumination apparatus to illuminate the first surface;
the spatial light modulation unit as set forth in claim 1; and
a projection optical system which forms the image of the first surface on the second surface, based on light from an illumination region formed on the first surface by the illumination apparatus;
wherein the spatial light modulator of the spatial light modulation unit is arranged on the first surface.

40. A device manufacturing method comprising:
preparing a photosensitive substrate;
arranging the photosensitive substrate on the second surface in the exposure apparatus as set forth in claim 39, and projecting an image of a predetermined pattern located on the first surface, onto the photosensitive substrate to effect exposure thereof;
developing the photosensitive substrate onto which the image of the pattern includes been projected, to form a mask layer in a shape corresponding to the pattern on a surface of the photosensitive substrate; and
processing the surface of the photosensitive substrate through the mask layer.

41. An exposure apparatus which projects an image of a first surface onto a second surface, the exposure apparatus comprising:
an illumination apparatus to illuminate the first surface;
the spatial light modulation unit as set forth in claim 15; and
a projection optical system which forms the image of the first surface on the second surface, based on light from an illumination region formed on the first surface by the illumination apparatus;
wherein the spatial light modulator of the spatial light modulation unit is arranged on the first surface.

42. A device manufacturing method comprising:
preparing a photosensitive substrate;
arranging the photosensitive substrate on the second surface in the exposure apparatus as set forth in claim 41, and projecting an image of a predetermined pattern located on the first surface, onto the photosensitive substrate to effect exposure thereof;
developing the photosensitive substrate onto which the image of the pattern includes been projected, to form a mask layer in a shape corresponding to the pattern on a surface of the photosensitive substrate; and
processing the surface of the photosensitive substrate through the mask layer.

43. An illumination apparatus which illuminates a first surface with light supplied from a light source, the illumination apparatus comprising:
the spatial light modulation unit as set forth in claim 1; and
a diffractive optical element which forms a first pupil luminance distribution with light not passing via the spatial light modulator of the spatial light modulation unit;
wherein a second pupil luminance distribution overlapping at least in part with the first pupil luminance distribution is formed with light from the spatial light modulator of the spatial light modulation unit.

44. An illumination apparatus which illuminates a first surface with light supplied from a light source, the illumination apparatus comprising:
the spatial light modulation unit as set forth in claim 15; and
a diffractive optical element which forms a first pupil luminance distribution with light not passing via the spatial light modulator of the spatial light modulation unit;
wherein a second pupil luminance distribution overlapping at least in part with the first pupil luminance distribution is formed with light from the spatial light modulator of the spatial light modulation unit.

45. An illumination apparatus which illuminates a first surface with light supplied from a light source, the illumination apparatus comprising:
a spatial light modulation unit comprising a spatial light modulator which applies spatial modulation to the light according to a position of incidence thereof; and
a diffractive optical element which forms a first pupil luminance distribution with light not passing via the spatial light modulator of the spatial light modulation unit;
wherein a second pupil luminance distribution overlapping at least in part with the first pupil luminance distribution is formed with light from the spatial light modulator of the spatial light modulation unit.

46. The illumination apparatus according to claim 45, wherein the spatial light modulator includes a plurality of reflecting elements arranged two-dimensionally, and
wherein the plurality of reflecting elements can be controlled independently of each other.

47. The illumination apparatus according to claim 46, wherein each of the reflecting elements of the spatial light modulator includes a reflecting surface, and
wherein inclinations of the reflecting surfaces of the reflecting elements can be controlled independently.

48. An exposure apparatus which projects an image of a first surface onto a second surface, the exposure apparatus comprising:
the illumination apparatus as set forth in claim 45, which illuminates the first surface; and
a projection optical system which forms the image of the first surface on the second surface, based on light from an illumination region formed on the first surface by the illumination apparatus.

49. A device manufacturing method comprising:
preparing a photosensitive substrate;
arranging the photosensitive substrate on the second surface in the exposure apparatus as set forth in claim 48, and projecting an image of a predetermined pattern located on the first surface, onto the photosensitive substrate to effect exposure thereof;
developing the photosensitive substrate onto which the image of the pattern includes been projected, to form a mask layer in a shape corresponding to the pattern on a surface of the photosensitive substrate; and
processing the surface of the photosensitive substrate through the mask layer.
